(19) United States
(12) Patent Application Publication
(10) Pub. No.: US 2010/0326492 A1
(43) Pub. Date: Dec. 30, 2010

(54) Photovoltaic Cell Support Structure Assembly

(75) Inventors: Kia Kuang Tan, Penang (MY); Robert Scott West, Pleasanton, CA (US); Nathanial James Czech, Airway Heights, WA (US); Edward Nicholas Caferro, Spokane, WA (US); Timothy Lee Treto, Spokane, WA (US); Wah Sheng Teoh, Penang (MY)

Correspondence Address: PATENT LAW GROUP LLP, 2635 NORTH FIRST STREET, SUITE 223, SAN JOSE, CA, 95134, US

(73) Assignees: SOLARMATION, INC., Spokane, WA (US); DSEM SYSTEMS TECHNOLOGY SDN. BHD., Penang (MY)

(21) Appl. No.: 12/495,598

(22) Filed: Jun. 30, 2009

(51) Int. Cl. H01L 31/052

(52) U.S. Cl. 136/246

(57) ABSTRACT

A plurality of CPV cells are mounted on a common ALOX™ plate. A copper interconnection layer is deposited over an insulating aluminum oxide surface of the ALOX™ plate. The interconnection layer connects all the CPV cells in series, so no wires are needed. In one embodiment, each CPV cell is mounted on a ceramic submount or an ALOX™ submount having an electrically insulating aluminum oxide layer formed in its bottom surface. Vias through the submount couple the cell electrodes to the copper interconnection pattern on the ALOX™ plate. The ALOX™ plate may be the heat sink or may be bolted or soldered to a separate heat sink. In one embodiment, edges of the ALOX™ plate are bent upwards, and side panels are affixed to the ALOX™ plate to create a box that supports a Fresnel lens that directs sunlight to each of the cells (e.g. nine) mounted on the ALOX™ plate.

### FIELD OF THE INVENTION

This invention relates to solar cells and, in particular, to a support structure for a concentrated photovoltaic cell that provides heat sinking and an electrical connection to other cells.

### BACKGROUND

A concentrated photovoltaic (CPV) system comprises an array of small solar cells (e.g., 1 cm² or less), where each cell receives light directed to it by an optical system that tracks the sun. The optical system for each cell typically has a light receiving area that is hundreds of times the area of the cell, so that the cell effectively receives energy from hundreds of suns.

A common optical system for a CPV system comprises a large area Fresnel lens, called a primary optical element (POE), that ideally focuses all of the impinging sunlight onto a receiving surface of a much smaller secondary optical element (SOE). The SOE is directly optically coupled to the cell. The SOE mixes the light from the POE and has the goal of providing uniform illumination of the cell. Alternatively, the optics may be a focusing mirror that receives light over a large area and focuses all the light onto the CPV cell.

Since the light from effectively hundreds of suns is absorbed by the cell, the cell gets very hot and needs substantial cooling. For example, the cell may need to dissipate 70 W so as not to exceed 100° C.

Many cells in a CPV system need to be connected in series to generate sufficient voltage for a typical power application. Each cell may generate around 6-7 amps at about 3 volts per cell if the sunlight is sufficient. A series connection of cells may generate up to 600 volts DC, which is then converted to 120 volts AC and then ran through a transformer for high voltage United States grid interconnect.

FIG. 1A is a schematic diagram of a plurality of triple-junction CPV cells 10 connected in series to achieve a desired voltage (e.g., 600 volts). Multiple strings are connected in parallel to achieve high currents and power. In a triple-junction CPV cell, each diode junction is sensitive to a different range of wavelengths, such as UV, visible, and infrared, to make more use of the sun's energy. A bypass diode 11 is forward biased when the CPV cell 10 is shaded or there is an open circuit (i.e., the voltage across the cell 10 exceeds the forward voltage of the diode 11) to allow current to flow through the remaining cells in the series and to prevent any high voltage across the cells causing the cells to break down.

FIG. 1B is another way of illustrating the cells 10 as three batteries in series.

Each cell has a metal anode electrode and a cathode electrode. FIG. 1C illustrates a possible electrode structure on the bottom surface of a CPV cell flip chip 12 where the anode and cathode electrodes 13 are both formed on the bottom surface. FIG. 1D illustrates a top surface of a non-flip chip CPV cell 14, where the cell has a large bottom electrode (not shown) and the top electrode 15 is a distributed edge electrode (to avoid blocking light) that is electrically connected to a metal layer on the support structure by one or more wire bonds.

FIG. 1E is a cross-sectional view of a typical CPV cell 14 containing three pn junctions 16 separated by a tunnel junction 17. The top n-layer is contacted by a semiconductor contact region 18, and the top electrode 15 is formed over the contact region 18. A bottom electrode 19 is formed on the bottom surface of the growth substrate 20. An anti-reflection coating 21 may be deposited over the top of the cell.

One type of prior art CPV module 22 is shown in FIG. 2, without the optical system for simplicity. A single cell 23 is thermally coupled to a ceramic submount 24 via solder 26 and a copper layer 28 on the submount 24. The copper layer 28 also provides an electrical path between the cell 23, a bypass diode 30, and electrical connectors 32 for connecting the cell 23 in series with identical modules 36. The anode and cathode electrical paths are shown by the two electrically isolated sections of the copper layer 28. One electrode of the cell 23 is connected to the copper layer 28 section directly beneath it, and the other electrode of the cell 23 is connected to the right side copper layer 28 section by a separate copper trace out of the plane of FIG. 2 or by a wire connected to the copper layer 28 section. If the cell 23 has both electrodes on its bottom side, it is referred to as a flip chip. A suitable electrical connector 38 connects modules 20 and 36 in series via a wire 40. Many more modules would also be connected in series and parallel by wires to generate the desired power.

The ceramic submount 24, with its soldered components on its top surface, needs to be thermally coupled to a large metal heat sink 44. Since the ceramic submount 24 is brittle, bolts are not passed through the ceramic submount 24. The ceramic submount 24 is affixed to an aluminum plate 46 via a suitable thermally conductive adhesive 48, such as a silver epoxy or other suitable material. If an epoxy is used, it needs curing, such as by heating the structure in an oven, which is time-consuming.

Another thermally conductive material 50 (e.g., a non-adhesive thermal grease) is then deposited on the heat sink 44, and the aluminum plate 46 is bolted to the heat sink with bolts 52. Any thermal coupling layer that is not a metal (e.g., solder or copper) adds significant thermal resistance.

The module 36 is identical to the module 22.

Some drawbacks of the module 22 are that: each thermal coupling layer (including the ceramic substrate) adds a thermal resistance; the module is time-consuming to fabricate due to the application and curing of the epoxy; the electrical connections between modules lowers reliability and increases part count; and the heat sinking is limited by the size of the module.

What is needed is a solar cell system that has better heat sinking than the prior art, has better reliability, and is easier and quicker to fabricate.

### SUMMARY

Various embodiments of support structures for CPV cells are described that provide an efficient thermal path to a heat sink and provide electrical connections to other CPVs on the same heat sink by a copper layer rather than by wires and connectors.

In one embodiment, a CPV cell is mounted on a ceramic submount or an aluminum submount having an electrically insulating aluminum oxide layer formed in its bottom surface. The aluminum submount may be an ALOX™ substrate. Vias through the submount couple the cell electrodes to a copper interconnection pattern on an aluminum oxide surface of an ALOX™ heat sink. The heat sink supports a plurality of cells. The interconnection pattern on the heat sink connects all cells in series so wires are needed.

In another embodiment, an array of cells is supported on a common ALOX™ plate without any submounts being used, and the cells are connected in series by a copper interconnection pattern formed over an aluminum oxide layer on the ALOX™ plate. The ALOX™ plate may be the heat sink or may be bolted or soldered to a separate heat sink.

By using a common ALOX™ plate, the heat from the cells spreads between the cells to increase the heat sinking.

In one embodiment, edges of the ALOX™ plate are bent upwards, and side panels are affixed to the ALOX™ plate to create a box that supports a large Fresnel lens. The lens directs sunlight to each of the cells (e.g. nine) mounted on the ALOX™ plate.

Various other designs are described that obviate the need for wires connecting cells in series. The designs maximize the use of metal paths to the heat sink to improve heat sinking.

### BRIEF DESCRIPTION OF THE DRAWINGS

FIGS. 1A and 1B are schematic diagrams of multiple CPV cells connected in series, with a bypass diode across each cell.

FIG. 1C illustrates a possible electrode structure on the bottom surface of a CPV cell flip chip.

FIG. 1D illustrates a top surface of a non-flip chip CPV cell, where the cell has a large bottom electrode (not shown) and the top electrode is an edge electrode that is electrically connected to a metal layer by one or more wire bonds.

FIG. 1E is a cross-sectional view of a typical CPV cell.

FIG. 2 is a cross-sectional view of two prior art CPV modules for being connected in series by a separate electrical connector.

FIG. 3A is a zig-zag cross-sectional view of a multiple cell system (only showing two cells for simplicity), illustrating one embodiment of the invention, where solder and copper are used for thermal conduction between the cells and an ALOX™ anodized aluminum substrate, with electrical connections to the cells being by vias through the ceramic submounts and a copper interconnection layer over the ALOX™ substrate, thus eliminating wires connecting the cells. In FIG. 3A, the cell has a bottom electrode connected to the via shown beneath the cell.

FIG. 3B is a partial top down view of the embodiment of FIG. 3A illustrating a possible copper layer pattern on the ceramic submount (or substrate) that can be used to connect both electrodes of a cell to the bypass diode and illustrating vias electrically connected to a copper interconnection layer on the ALOX™ substrate.

FIG. 3C is a transparent top down view of the embodiment of FIG. 3A illustrating the metal on the bottom of the submount and showing the connection to the copper interconnection layer on the ALOX™ substrate.

FIG. 4 illustrates another embodiment of the invention similar to FIG. 3A but where the ALOX™ substrate is soldered to a copper layer on the heat sink.

FIG. 5 illustrates another embodiment of the invention, where a separate ALOX™ substrate is not used, and where solder and copper are used for thermal conduction between the cells and an ALOX™ anodized aluminum heat sink, with electrical connections to the cells being by vias through the ceramic submounts and a copper interconnection layer over the ALOX™ heat sink.

FIG. 6A illustrates another embodiment of the invention similar to FIG. 5 except that the cell includes an isolated thermal pad on its bottom surface that is efficiently coupled to the heat sink without an intervening aluminum oxide layer. The two electrodes of the cell are connected to a copper interconnection layer on an ALOX™ heat sink by vias through the submount, although the cross-section passes through only a single via.

FIG. 6B is a top down view of the embodiment of FIG. 6A showing the interconnection between the cell, diode, and vias on the submount and showing a portion of the copper interconnection layer on the ALOX™ heat sink.

FIG. 6C is a transparent top down view of the embodiment of FIG. 6A showing the metal on the bottom of the submount, where the vias are electrically connected to the copper interconnection layer on the ALOX™ heat sink, and the electrically isolated thermal pad is connected to the copper layer directly on the aluminum of the heat sink.

FIG. 7 is similar to FIG. 6A but with the ceramic submount thinned under the cells and filled with metal for better thermal conductivity.

FIG. 8 illustrates another embodiment of the invention where the cell is mounted on an electrically insulating ALOX™ submount rather than a ceramic submount, and the ALOX™ submount is soldered to the heat sink.

FIG. 9 illustrates how the electrodes on the top of the submount of FIG. 8 can be coupled to electrodes on another submount for interconnecting cells on the same heat sink without wires.

FIG. 10A illustrates another embodiment of the invention wherein the cell is mounted on an ALOX™ submount rather than a ceramic submount, wherein the ALOX™ submount is soldered to the heat sink, and wherein the ALOX™ submount has vias for conducting current to an underlying copper layer formed on an ALOX™ heat sink.

FIG. 10B is a top down view of the embodiment of FIG. 10A showing the interconnection between the cell, diode, and vias on the top of the submount and showing a portion of the copper interconnection layer on the ALOX™ heat sink.

FIG. 11 illustrates another embodiment of the invention where the cells are mounted on an electrically insulating surface of an ALOX™ heat sink using a patterned copper layer and solder, where the cells are connected in series is via the copper layer.

FIG. 12 illustrates the module of FIG. 11 with a secondary optical element (SOE) over one of the cells.

FIG. 13 illustrates an embodiment where cells are electrically connected to the heat sink body via a copper layer and solder, and cells are connected in parallel using the heat sink body and an insulated copper layer.

FIG. 14 illustrates an embodiment similar to FIG. 13 but where the cells are connected in series by a copper layer, and the heat sink body has insulated sections.

FIG. 15 is a top down view illustrating how nine cells can be connected in series using a copper layer on a shared ALOX™ heat sink.

FIG. 16 illustrates the embodiment of FIG. 15 with the sides of the ALOX™ heat sink bent upwards to form sides of a box.

FIG. 17 illustrates the embodiment of FIG. 16 with side panels attached to the ALOX™ heat sink and a top Fresnel lens for focusing sunlight onto each cell using the SOE of FIG. 12.

FIG. 18 is a simplified view of the Fresnel lens of FIG. 17, having nine sublenses where each sublens focuses sunlight onto its associated underlying cell in FIG. 15.

FIG. 19 illustrates four identical units of FIG. 16 connected together by elongated side panels, with a Fresnel lens over each set of cells.

FIG. 20 is a perspective view of a single cell module, where a copper layer on an ALOX™ substrate is connected to the cell's anode and cathodes electrodes and terminates in pads for being contacted by an electrical connector or wire bonds.

Elements labeled with the same numerals in the various figures are the same or equivalent.

### DETAILED DESCRIPTION

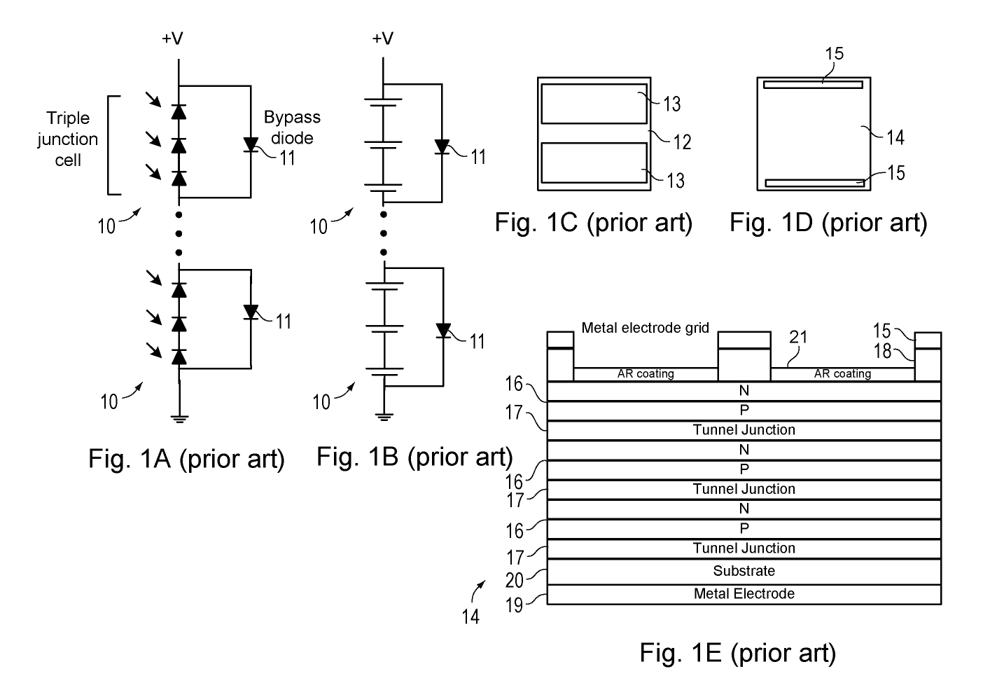

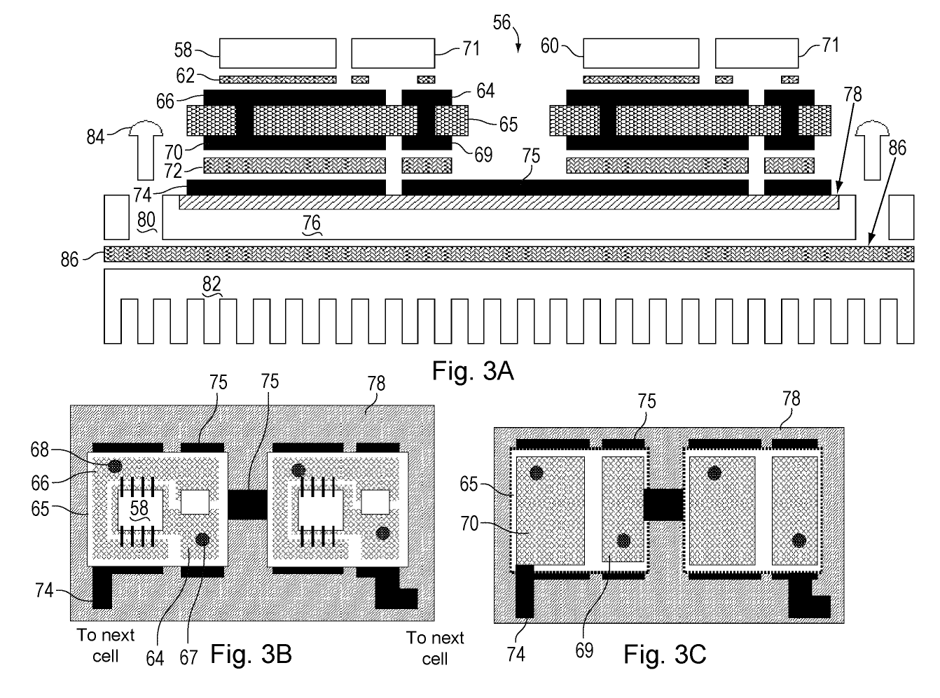

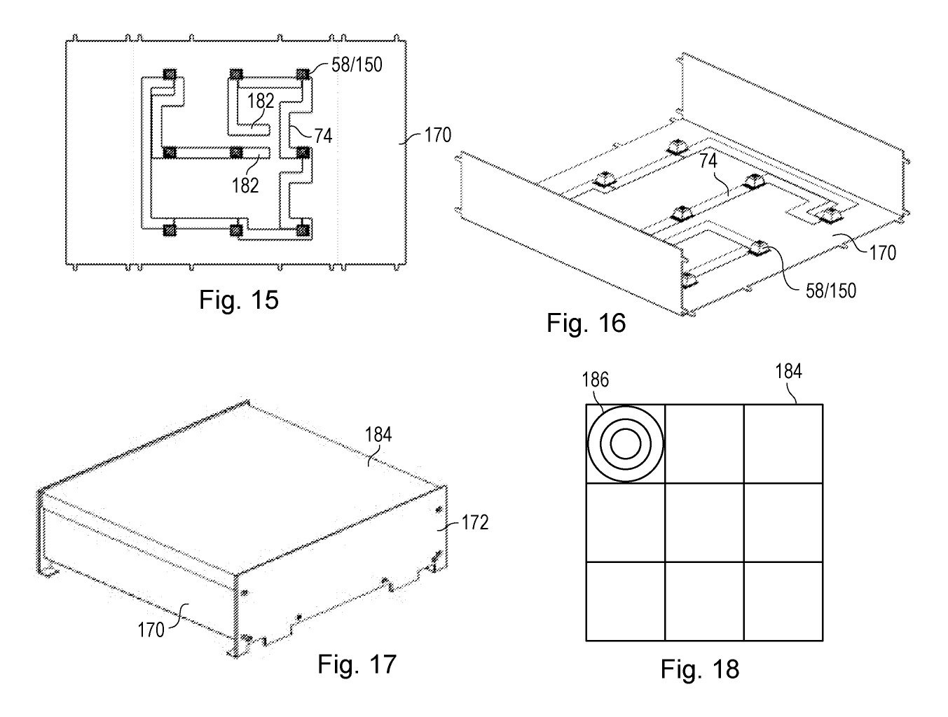

FIG. 3A is a zig-zag cross-sectional view of a bolt-down CPV cell module 56 that contains two cells 58 and 60 electrically connected in series. In an actual embodiment, there are nine cells connected in series on a single ALOX™ substrate, as shown in FIG. 15, described later. The cells 58 and 60 may be triple-junction CPV solar cells, such as depicted in FIGS. 1A-1E.

FIG. 3B is a top down view of the copper pattern on the submount, and FIG. 3C is a transparent top down view showing the metal on the bottom of the submount.

In FIG. 3A, the solar cell's 58 bottom electrode is soldered via a solder layer 62 to a copper layer portion 64 (better shown in FIG. 3B) formed on a surface of a ceramic (e.g., Al₂O₃) submount 65, also referred to as a substrate. The solder may be any suitable metal alloy. Forming metal conductors on a ceramic submount is well known and may be performed by sputtering, evaporation, printing, plating, or other technique. The copper layer portion 64 (and others mentioned herein) may be a copper alloy and may include layers of Cu, Ni, and Au. The ceramic submount 65 in one embodiment is about 400 microns thick.

The solar cell's 58 top electrode is wire bonded to a copper layer portion 66 (FIG. 3B) on the surface of the submount 65.

The submount 65 may instead be an ALOX™ submount, described in more detail with respect to FIG. 8.

The ceramic submount 65 has vias 67 and 68 (see FIG. 3B) formed through it that are filled with the copper material, and the vias 67 and 68 lead to a first bottom copper layer portion 69 and a second bottom copper layer portion 70, respectively. Since copper has a thermal conductivity of about 400 W/mK and the Al₂O₃ ceramic has a thermal conductivity of about 24 W/mK, the copper vias greatly improve the thermal conductivity between the cell 58 and the heat sink. There may be additional copper vias for increased thermal conductivity.

A bypass diode 71 is also soldered to the copper layer portions 64 and 66 and is electrically connected to the bottom copper layer portions 69 and 70 by the vias 67 and 68 (FIG. 3B).

The bottom copper layer portions 69 and 70 are soldered, via a solder layer 72, to patterned copper layer portions 74 and 75, respectively, deposited on an insulating aluminum oxide layer 78 surface of an ALOX™ substrate 76. The copper layer portions 74 and 75 are patterned so that the copper portions are electrically isolated from each other. The ALOX™ substrate 76 is a conductive aluminum plate that is masked using conventional lithography techniques. The exposed portions are anodized by immersing the aluminum in an electrolytic solution and applying current through the aluminum and the solution. Oxygen is released at the surface of the aluminum, producing an aluminum oxide layer 78 having nanopores. The aluminum oxide layer 78 may be formed to any depth. Aluminum oxide is ceramic in nature and is a highly insulating dielectric material with a thermal conductivity between 20-30 W/mk. The aluminum oxide layer 78 can be made thin so as not to add significant thermal resistance. The unexposed ALOX™ substrate 76 has a very high thermal conductivity on the order of 250 W/mk. Anodizing aluminum is a well known process for providing a protective layer over aluminum and for creating a porous surface for receiving an overcoating of material.

A resin (a polyimide) is then diffused into the porous aluminum oxide layer 78 to planarize the surface. The ALOX™ substrate 76 is again masked to expose a portion of the aluminum oxide layer 78 (defining the copper layer portions 74 and 75), and the copper layer portions 74 and 75 (which may be layers of Cu, Ni, and Au) are deposited by sputtering, printing, plating, or any other suitable process. The copper layer portions 74 and 75 enable simple soldering of the ceramic submount bottom copper layer portions 69 and 70 to the copper layer portions 74 and 75 on the ALOX™ substrate 76, and provides a thermally and electrically conductive material between the cell 58 and the heat sink.

ALOX™ substrates with a copper layer may be made to any size and configuration by Micro Components, Ltd, and Device Semiconductor Sdn. Bhd. (DSEM). Forming ALOX™ substrates is described in US patent application publication US 2007/0080360 and PCT International Publication Number WO 2008/123766, both incorporated herein by reference. The tradename “ALOX™” (coined by Micro Components, Ltd ) is used herein to identify the particular brand of substrate 76 used in the preferred embodiment, but the substrate 76 can be a non-tradename aluminum substrate with an oxidized surface portion and a copper layer (or other metal layer to aid soldering) deposited on the oxidized surface.

Any number of identical sets of cells, diodes, and ceramic submounts may be soldered onto the various copper layer portions to share the ALOX™ substrate 76 as part of a heat sink/interconnect layer and to create a single multi-cell module that can be simply handled.

In FIG. 3B, the ends of the copper layer portions 74 and 75 continue along the ALOX™ substrate 76 to connect to similar copper layer patterns associated with adjacent cells to interconnect any number of cells in series.

Holes 80 are drilled near the corners of the ALOX™ substrate 76, and the ALOX™ substrate 76 is bolted onto a large metal heat sink 82 (e.g., aluminum) by metal bolts 84 (e.g., screws). A thin thermal grease layer 86 or other non-adhesive thermal layer (for improving thermal contact between the surfaces) is provided between the ALOX™ substrate 76 and the metal heat sink 82 to increase the thermal conductance to the heat sink 82. Enabling bolting of the ALOX™ substrate 76 to a heat sink allows the ALOX™ substrate 76 to be thermally connected to any suitable heat sink by a customer and be replaced if necessary. In another embodiment, the ALOX™ substrate 76 serves as the only heat sink.

In one embodiment, the ALOX™ substrate 76 is on the order of about 1-3 mm thick. The module 56 without the heat sink 86 or optical system is only about 4 mm thick, and the primary thermal path between the cell 58 and the metal heat sink 82 is all metal except for the thin thermal grease layer 86. The wide ALOX™ substrate 76 helps spread out the heat from the different cells 58 and 60 (there would be many more) over a wide area of the heat sink 82 to further improve the removal of heat from the cells. The heat sink 82 shown uses fins to increase surface area, but the heat sink 82 may be any shape or size. The ALOX™ substrate 76 itself may be the only heat sink, and its edges may be extended and bent downwards to create fins for increasing the air/metal interface area.

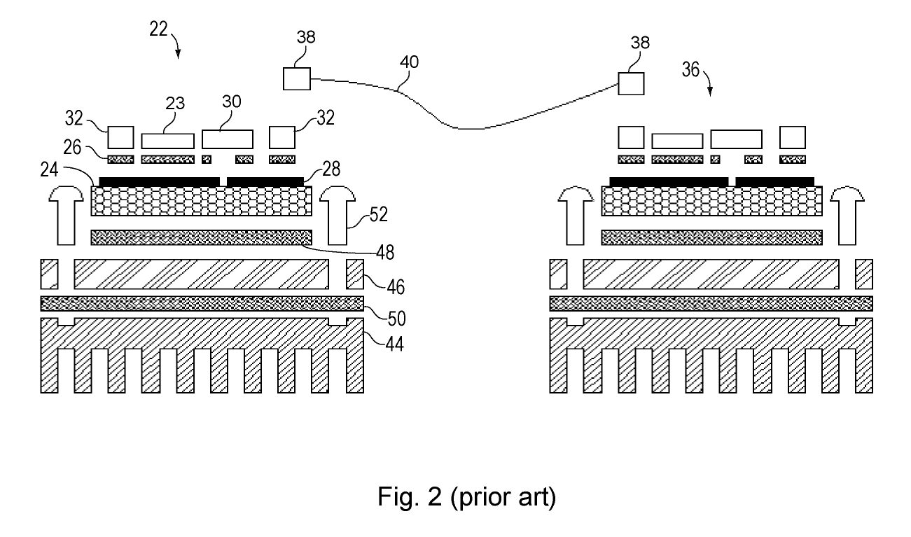

All electrical connections between the cells and diodes are made by the various copper layers and vias, so there are no resistance and reliability problems that would exist when using separate connectors and wires as shown in the prior art FIG. 2. The cell 58 is connected in reverse parallel with the diode 71, as shown in FIG. 1A.

If the cell 58 is a flip chip, the shapes of the copper layer portions 64 and 66 would be different but the remainder of the structure may be substantially the same.

The soldering of the layers in FIG. 3A may be performed on a large scale using conventional soldering reflow techniques generally employed for the use of electronic circuitry. In another embodiment, one or more of the soldering layers is replaced by a silver epoxy (or other metal-loaded epoxy) that provides good adhesion and good electrical and thermal conductivity.

Using the aluminum oxide layer 78 formed in the ALOX™ substrate 76 is far superior than laminating a dielectric sheet over a metal substrate and printing a copper pattern over the dielectric. This is because the cyclical heat and different thermal coefficients of expansion could delaminate any layers over time, and such delamination is obviated by the aluminum oxide layer. Additionally, in cases where the cell has a large electrically insulated thermal pad on its bottom surface, there is no reason to provide a dielectric layer in the thermal path to the heat sink. Deleting a dielectric layer in the thermal path would not be possible using a standard metal core PCB since the entire surface of the metal core PCB is coated with a laminated dielectric layer. However, by using an ALOX™ substrate or ALOX™ heat sink, the aluminum oxide layer 78 may only be formed below the copper interconnection portions and not in the thermal path.

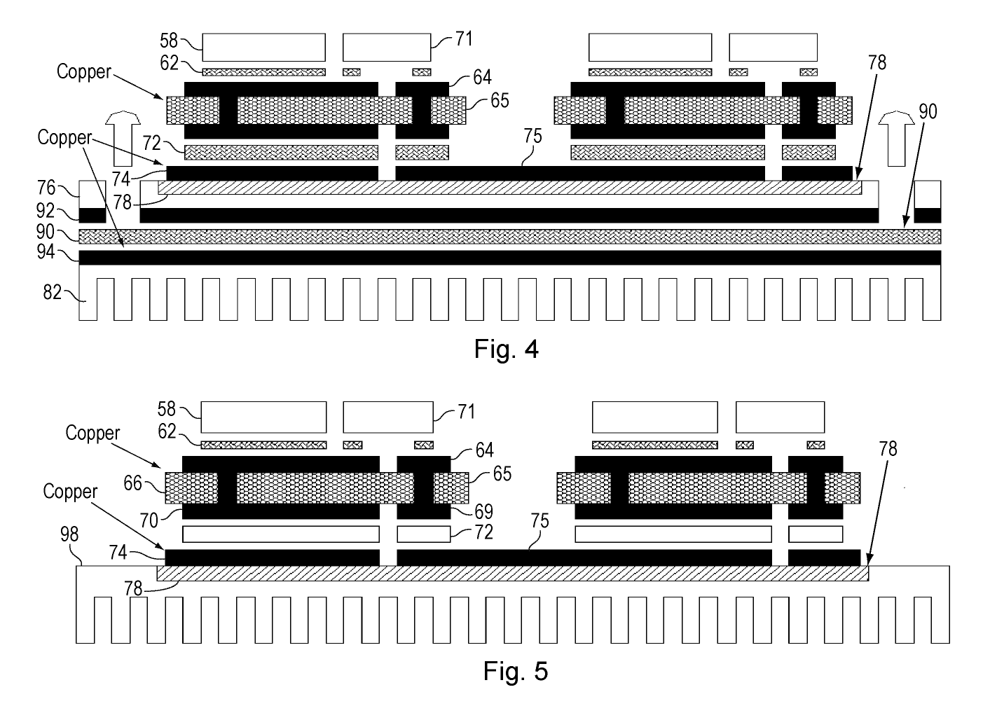

FIG. 4 is similar to FIG. 3A but replaces the thermal grease layer 86 with a solder layer 90 between copper layers 92 and 94. Copper layers 92 and 94 are deposited on the bottom of the ALOX™ substrate 76 and the top of the heat sink 82, respectively. Since the layers are soldered, bolting the ALOX™ substrate 76 to the heat sink 82 is optional.

FIG. 5 is similar to FIG. 3A but makes the ALOX™ substrate the heat sink 98 by providing fins. The ALOX™ heat sink 98 may be made any suitable thickness. All electrical connections between cells are made by the patterned copper layer 74 deposited on the aluminum oxide layer 78 formed in the heat sink 98, using the anodizing process previously described.

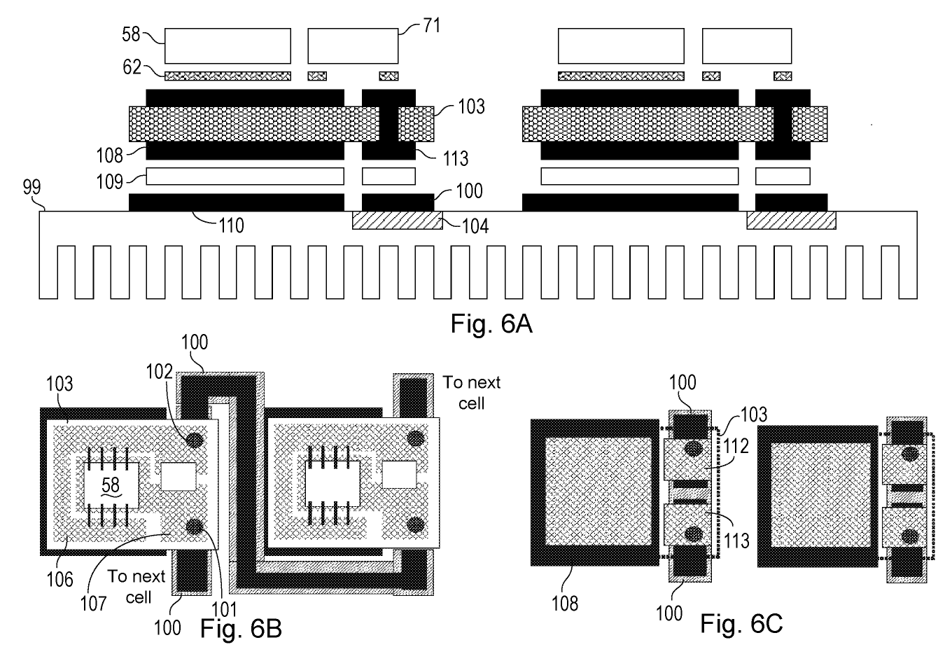

FIG. 6A illustrates another embodiment of the invention similar to FIG. 5 except that the cell 58 also includes an isolated thermal pad on its bottom surface that is efficiently coupled to the heat sink 99. The two electrodes of the cell 58 are connected to a patterned copper interconnection layer 100 on the ALOX™ heat sink 99 by vias 101 and 102 (FIG. 6B) through the ceramic submount 103, although the cross-section passes through only a single via. The copper interconnection layer 100 is deposited over a patterned aluminum oxide layer 104 formed in the ALOX™ heat sink 99. The copper interconnect layer 100 is electrically insulated from the aluminum portion of the heat sink 99, and the copper interconnect layer 100 extends out of the plane of the figure to electrically connect to adjacent cell electrodes for the series connection.

In another embodiment, one of the electrode vias (e.g., for the backside cell electrode) is electrically connected to a copper layer portion directly on an aluminum portion of the heat sink 99 so that the aluminum heat sink 99 conducts the current for that electrode. Cells may be connected in parallel in such a way.

FIG. 6B is a top down view of the embodiment of FIG. 6A showing the metal interconnection between the cell, diode, and vias on the top of the submount 103 and showing a portion of the patterned copper interconnection layer 100 on the ALOX™ heat sink 99. The top cell electrode is wire-bonded to a first metal portion 106, and the backside cell electrode is directly bonded to a second metal portion 107. A third metal portion on the top of the submount 103 (covered by the cell) is directly bonded to an electrically isolated thermal pad on the back of the cell 58.

FIG. 6C is a transparent top down view of the embodiment of FIG. 6A showing the metal on the bottom of the submount 103 and showing the connection to the copper interconnection layer 100 on the ALOX™ heat sink 99. The thermal copper pad 108 on the bottom of the submount 103 is shown in FIG. 6A soldered (by solder 109) to a copper layer portion 110 directly formed on the aluminum portion of the heat sink 99, since the thermal copper pad 108 is electrically isolated from the cell 58. The metal electrodes 112 and 113 on the back of the submount 103 are soldered to the copper interconnection layer 100 over the heat sink 99.

In one embodiment, an electrode of a cell is electrically connected to the metal heat sink 99 so the heat sink acts as an electrical conductor for interconnecting cells.

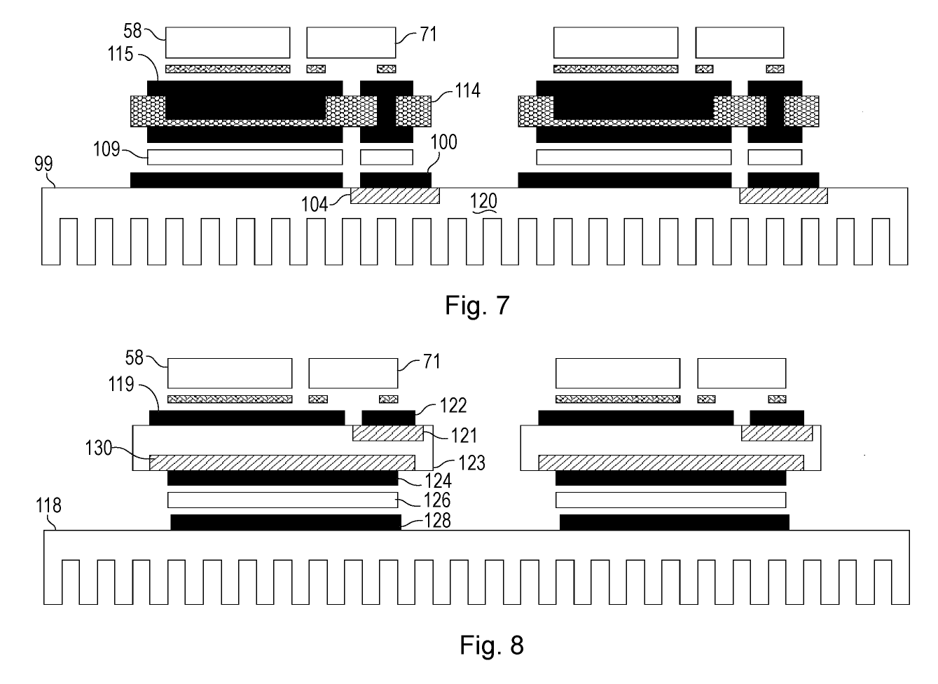

FIG. 7 is similar to FIG. 6 but the ceramic submount 114 is molded to have a sunken well which is filled with copper 115 to reduce the thermal conductivity through the ceramic submount 114.

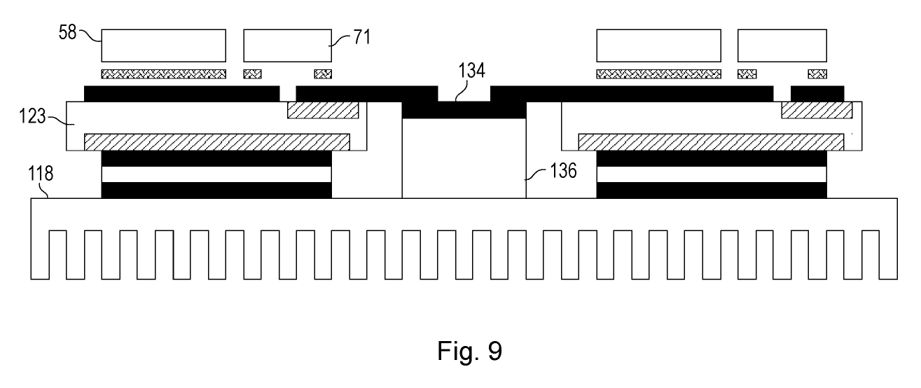

FIG. 8 illustrates multiple cells mounted on a common heat sink 118, and the cell electrodes may be connected to other cells using any form of interconnection, such as vias through the submount and insulated copper layer portions on the heat sink or other shared substrate, or raised copper layers (FIG. 9), or any other connection disclosed herein. In FIG. 8, the cell 58 has either a bottom electrode or an electrically insulated thermal pad soldered to a copper layer 119 on the aluminum portion of an ALOX™ submount 123. An aluminum oxide portion 121 electrically insulates the copper layer portion 122 connected to one of the cell electrodes. The ALOX™ submount 123 is attached to the metal heat sink 118 by a copper layer 124, a solder layer 126, and a copper layer 128 for good thermal conductivity. An aluminum oxide layer 130 on the bottom of the ALOX™ submount 123 electrically insulates the copper layer 119 from the heat sink 118. This configuration provides good thermal conductivity since the heat from the cell 58 is spread throughout the entire ALOX™ submount 123 since there is no low-thermal conductivity layer between the bottom of the cell 58 and the aluminum portion of the ALOX™ submount 123. This configuration is much better than if the aluminum oxide layer 130 were located on the top surface of the ALOX™ submount 123, since the aluminum oxide would generally only conduct heat vertically so there would be no heat spreading throughout the ALOX™ submount 123. The cell 58 may use the electrical conduction of the ALOX™ submount 123 to interconnect to other cells. If only the cell's electrically isolated thermal pad were soldered to the ALOX™ submount 123, no aluminum oxide layer 130 would be needed if the electrode inteconnections just used a copper layer over an aluminum oxide layer 121 on the ALOX™ submount 123.

FIG. 9 illustrates the structure of FIG. 8 and additionally illustrates how cells may be electrically interconnected by a raised copper layer 134 supported by an insulator 136, such as FR4 or other insulating material. The FR4 could entirely fill the gaps between the ALOX™ substrates 123 so the copper layer 134 is completely supported. Vias may also be used to electrically connect cell electrodes to a copper interconnection layer on an ALOX™ heat sink.

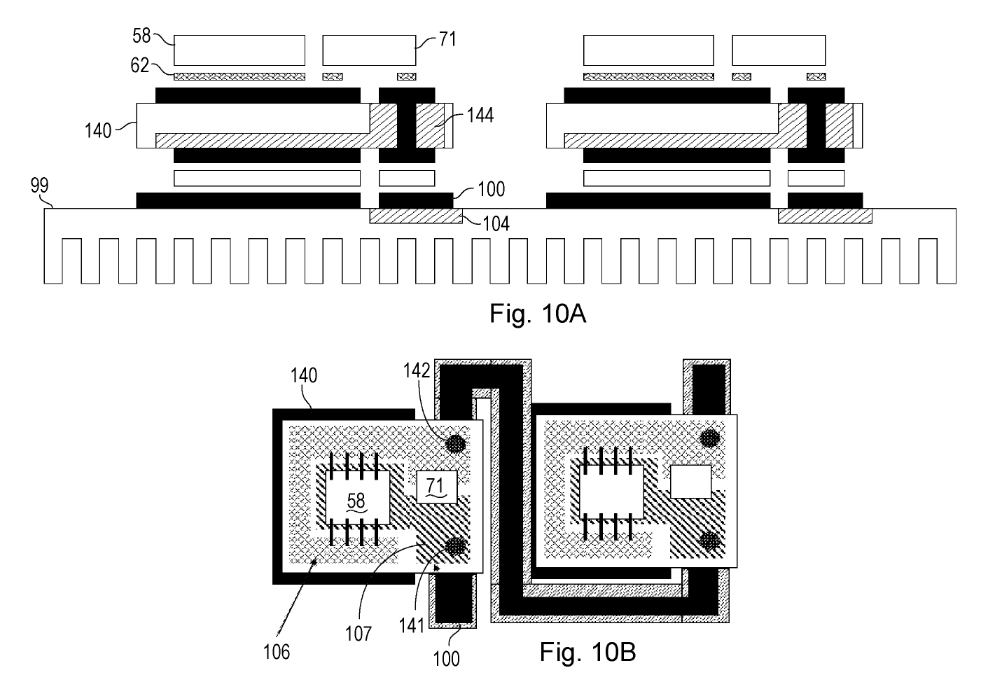

FIG. 10A illustrates another embodiment using an ALOX™ submount 140 to support the cell 58 and diode 71, but where the ALOX™ submount 140 includes two copper filled vias 141 and 142 (FIG. 10B) electrically insulated from the aluminum by an aluminum oxide portion 144. The vias 141 and 142 allow the cell and diode electrodes to be electrically connected in series with adjacent cell/diode electrodes using a patterned copper interconnect layer 100 formed on an aluminum oxide portion 104 of an ALOX™ heat sink 99. Alternatively, the vias can be isolated non-anodized portions of the ALOX™ submount 140. The vias are electrically connected to electrodes of other cells by the patterned copper layer 100 over the ALOX™ heat sink 99.

FIG. 10B is a top down view of the ALOX™ submount 140, showing the metal portions 106 and 107 (like in FIG. 6B) connected to the vias 142 and 141. If the cell 58 uses a thermal pad, the bottom of the ALOX™ submount 140 may be similar to that shown in FIG. 6C.

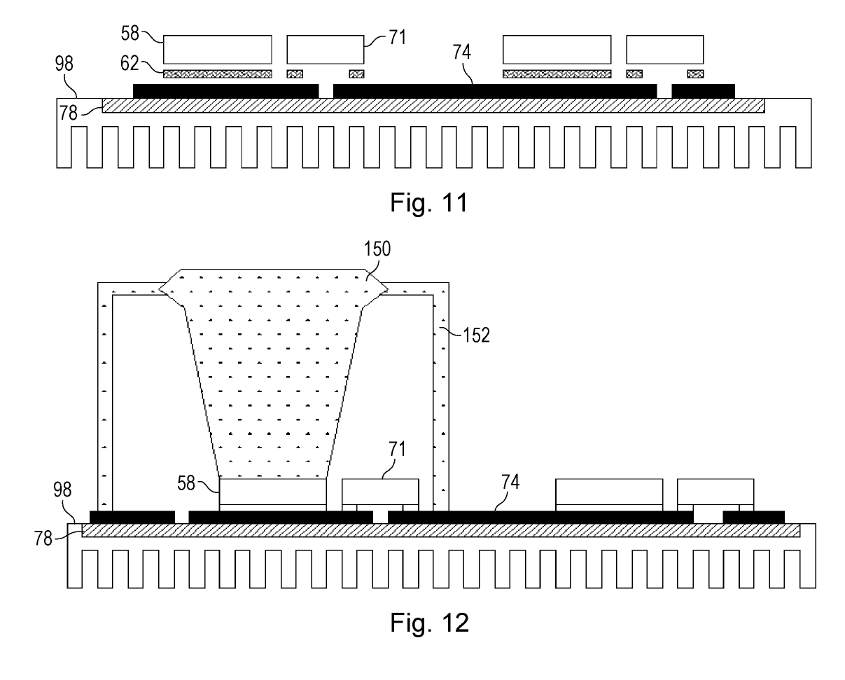

FIG. 11 illustrates an embodiment where there is no intermediate support structure (no submount) for the cell 58 and diode 71. An ALOX™ heat sink 98 has a top aluminum oxide portion 78 that has a patterned copper layer 74 deposited on it. The cell 58 and diode 71 are electrically connected to the copper layer 74 by a solder layer 62. The cell/diode electrodes are electrically connected to adjacent cell/diode electrodes by the copper layer 74, as in FIG. 5. If there were additional cells to the left or right of those in FIG. 11, which are in the preferred embodiment, the same type of interconnection would be repeated to create a series string of cells/diodes. The top view of the structure may resemble that of FIG. 10B without the vias. If a thermal pad is used, the thermal pad would be soldered to the aluminum portion of the ALOX™ heat sink 98 without any aluminum oxide layer in the thermal path since the cell's thermal pad is electrically insulated.

FIG. 12 illustrates the structure of FIG. 11 and also depicts a secondary optical element (SOE) 150 connected to the top of the cell 58, where the SOE 150 has an integrated support structure 152 that is affixed to the copper layer 74. Many other types of optical systems can be used. The SOE 150 receives concentrated sunlight from a large primary optical element, such as a Fresnel lens or a mirror, and mixes the light to substantially uniformly illuminate the surface of the cell 58. The SOE 150 has a substantially square shaped top down view.

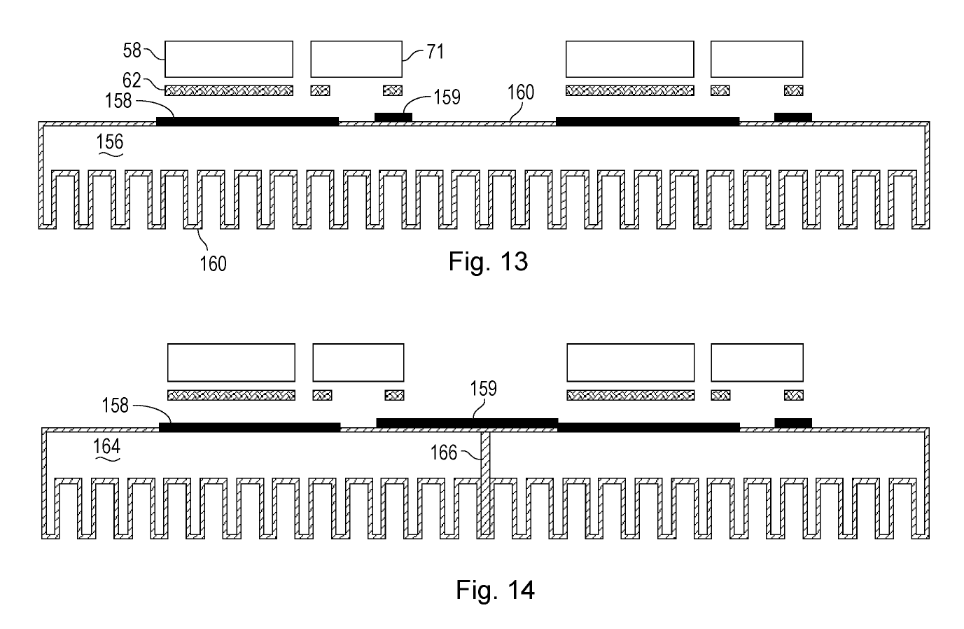

FIG. 13 illustrates an embodiment where the cell 58 has a bottom electrode electrically connected to an aluminum portion of the ALOX™ heat sink 156 by a solder layer 62 and a copper layer portion 158. The heat sink 156 electrically interconnects a plurality of cells in parallel. The other cell electrode is coupled to a copper layer portion 159 deposited over an aluminum oxide portion 160. The insulated copper layer portion 159 may be connected to other cells in parallel or to a power terminal. The entire outer surface of the heat sink 156 is anodized to create an electrically insulating shell except where the copper layer portion 158 is intended to directly contact the aluminum.

FIG. 14 is similar to FIG. 13 except that the copper layer 159 is patterned so that an electrode of one cell/diode is connected in series with the electrode of an adjacent cell/diode to create a series connection. The ALOX™ heat sink 164 has an aluminum oxide inner wall 166 extending completely through the heat sink 164 to electrically isolate one portion of the heat sink 164 from an adjacent portion, each portion being associated with a single cell. In one embodiment, there are nine isolated portions (see FIG. 15) and the electrical connection pattern shown in FIG. 14 would be repeated in two dimensions to connect each cell on the heat sink 164 in series.

FIG. 15 is a top down view of nine series-connected cells 58 covered by the SOEs 150 in FIG. 12 supported on a single ALOX™ heat sink 170. A cross-section view may be similar to FIG. 12. Unlike the structures of the prior art FIG. 2, the large heat sink 170 removes more heat since it extends between the cells and thus has a larger surface area. The heat sink 170 may be 1 mm thick or more and may be substantially square with 1 foot sides. The two ends of the series string are terminated by connectors 182 that may be exposed below the heat sink 170. Wires or other means may be connected to the connectors 182 to string together groups of nine cells in series or parallel until the voltage produced is approximately 600 volts. In one embodiment of a CPV system, over 200 cells are connected in series and multiple series strings are connected in parallel.

FIG. 16 illustrates the embodiment of FIG. 15 with the sides of the ALOX™ heat sink 170 bent upwards to form sides of a box.

FIG. 17 illustrates the embodiment of FIG. 16 with side panels 172 attached to the ALOX™ heat sink 170 and a top Fresnel lens 184 for focusing sunlight onto each cell using the SOE 150 of FIG. 12.

FIG. 18 depicts a Fresnel lens 184 as a primary optical element (POE) for the nine cells 58 of FIG. 16, where the lens 184 is divided into nine identical lenses corresponding to each cell position. Each of the nine sections may focus the light of hundreds of suns on a corresponding cell area. The secondary optical element (SOE) 150 of FIG. 12 may be used for each cell 58 to mix the incoming light to create a uniform distribution of light over the cell surface. The lens 184 is about the same size as the heat sink 170 and is connected to it by tabs or screws to maintain alignment. Each cell may have sides less than 10 mm, and the SOE 150 may have a height less than 12 mm. One lens 186 is shown having concentric rings of angled prisms to generally focus the light within the SOE of an associated cell.

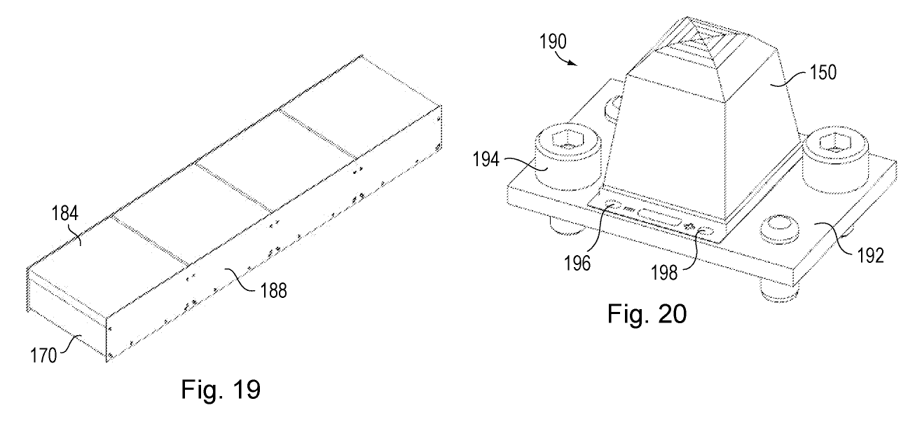

FIG. 19 illustrates four identical modules (FIG. 18) connected together by elongated side panels 188. Any size unit may be formed for ease of handling and interconnection.

FIG. 20 is a perspective view of a single cell module 190 that uses an ALOX™ substrate 192, that may be similar to any of the structures described above, where the SOE 150 (similar to that of FIG. 12) is affixed over the substrate 192. The ALOX™ substrate 192 is provided with bolts 194 for bolting the structure to a heat sink, such as in FIG. 3A. The heat sink may be shared by many cells. Electrodes 196 and 198 are extensions of a patterned copper layer over the aluminum oxide top surface of the ALOX™ substrate 192, and the electrodes 196 and 198 are connected to other modules using a suitable connector, such as a clamp that has electrodes matching the electrode 196 and 198 locations, with a wire connecting the connectors between cells. Alternatively, wires can be bonded directly to the electrodes 196 and 198 for connection to electrodes on other modules. Any of the structures described herein can be adapted for creating the single cell module of FIG. 20. The single cell module embodiment is particularly useful where customers want the flexibility of using the module in any configuration and on any type of heat sink, although the integrated systems of FIGS. 3-19 are preferred for increased efficiency, reliability, and ease of installation.

Accordingly, various heat sinks and electrical structures have been described for a solar cell that use a minimal number of non-metal interface layers to achieve good thermal conductivity to the heat sink, and where a plurality of cells supported by a single heat sink panel can be connected in series by an integrated copper layer that is also used as a heat transmitting layer. Combinations of the features of the various embodiments may also be made to create a module.

The term “aluminum,” when referring to an ALOX™ type substrate or heat sink, may include an aluminum alloy. The term “copper layer” is use to describe a metal layer containing a copper or copper alloy layer. The various metal layers may be other then copper, such as aluminum; however, copper is a better conductor of electricity and heat. Further, the metal interconnection layer on the ALOX™ type substrate or heat sink can be a conductive paste (e.g., silver or copper), metal-based ink, or other highly conductive layer. The metal interconnection layer may be printed or deposited in any suitable manner so as to have the desired interconnection pattern between cells.

Having described the invention in detail, those skilled in the art will appreciate that given the present disclosure, modifications may be made to the invention without departing from the spirit and inventive concepts described herein. Therefore, it is not intended that the scope of the invention be limited to the specific embodiments illustrated and described.

What is claimed is:

1. A concentrated photovoltaic (CPV) module comprising:
a plurality of CPV cells, including a first cell and a second cell, each cell having at least a first electrode and a second electrode;
an aluminum plate having an anodized top surface portion, the anodized top surface portion being an electrically insulating aluminum oxide portion, the plurality of cells being mounted over the aluminum plate;
a patterned first metal interconnection layer deposited over at least a portion of the aluminum oxide portion; and
at least the first electrode of the first cell and the second electrode of the second cell being electrically interconnected, without wires, by the first metal interconnection layer, the plurality of cells being thermally coupled to the aluminum plate.

2. The module of claim 1 further comprising a heat sink, wherein the aluminum plate is thermally coupled to the heat sink.

3. The module of claim 2 wherein the aluminum plate is affixed to the heat sink.

4. The module of claim 1 wherein the aluminum plate is a heat sink having fins.

5. The module of claim 1 further comprising:
a plurality of submounts, each submount having at least two top electrodes on a top surface and at least two bottom electrodes on a bottom surface, wherein vias through the submount connect the top electrodes to corresponding ones of the bottom electrodes, the first cell having its first electrode connected to one of the top electrodes on a first submount and having its second electrode connected to another one of the top electrodes on the first submount, the second cell having its first electrode connected to one of the top electrodes on a second submount and having its second electrode connected to another one of the top electrodes on the second submount; and
the bottom electrodes of the submounts being electrically coupled to the patterned first metal interconnection layer, wherein the first metal interconnection layer interconnects the plurality of CPV cells.

6. The module of claim 5 wherein each of the submounts comprises a ceramic.

7. The module of claim 5 wherein each of the plurality of submounts comprises an aluminum submount having an insulating aluminum oxide layer formed in its bottom surface, the aluminum oxide layer being thermally coupled to the aluminum plate.

8. The module of claim 1 wherein the first electrode of the first cell is a bottom electrode of the first cell soldered to a first portion of the first metal interconnection layer, and wherein the second electrode of the second cell is electrically connected to the first portion of the first metal interconnection layer for electrically interconnecting the first cell and the second cell.

9. The module of claim 1 wherein the plurality of cells include a metal thermal pad on a bottom surface, the thermal pad being electrically insulated from the first electrode and the second electrode on each of the cells, the thermal pad being soldered to the aluminum plate.

10. The module of claim 1 further comprising:
a plurality of submounts, each submount having at least two top electrodes on a top surface and at least two bottom electrodes on a bottom surface, wherein vias through the submount connect the top electrodes to corresponding ones of the bottom electrodes, the first cell having its first electrode connected to one of the top electrodes on a first submount and having its second electrode connected to another one of the top electrodes on the first submount, the second cell having its first electrode connected to one of the top electrodes on a second submount and having its second electrode connected to another one of the top electrodes on the second submount;
the bottom electrodes of the submounts being electrically coupled to the patterned first metal interconnection layer, wherein the first metal interconnection layer at least partially interconnects the plurality of CPV cells;
wherein the plurality of cells include a metal first thermal pad on a bottom surface of each cell, the first thermal pad being electrically insulated from the first electrode and the second electrode on each of the cells, the first thermal pad being soldered to a second thermal pad on the top surface of each of the submounts, each of the submounts having a third thermal pad on the bottom surface of the submount, the third thermal pad being thermally coupled to the aluminum plate.

11. The module of claim 1 wherein the first electrode of the first cell is a bottom electrode of the first cell electrically connected to a first portion of the first metal interconnection layer, and wherein the second electrode of the second cell is electrically connected to the first portion of the first metal interconnection layer for connecting the first cell and the second cell in series.

12. The module of claim 1 wherein the aluminum plate has its outer surface covered with an aluminum oxide layer except in areas that are electrically connected to the first electrode of each of the cells so that the aluminum plate conducts current generated by the cells.

13. The module of claim 1 wherein the aluminum plate has its outer surface covered with an aluminum oxide layer except in areas that are electrically connected to the first electrode of each of the cells, the aluminum plate having internal aluminum oxide walls that electrically isolate each of the cells mounted over the aluminum plate, the first metal interconnect layer interconnecting the cells in series.

14. The module of claim 1 wherein the aluminum plate has its outer surface covered with an aluminum oxide layer except in areas that are thermally coupled to a thermal pad on a bottom surface of each of the cells.

15. The module of claim 1 wherein the aluminum plate has edges that are bent downwards to form fins.

16. The module of claim 1 wherein the aluminum plate has edges that are bent upwards to form at least a partial box around the plurality of cells, the partial box forming a support for a primary optical element that directs sunlight to each of the cells.

17. The module of claim 16 further comprising side panels connected to the partial box for enclosing the cells mounted on the aluminum plate.

18. The module of claim 16 wherein the aluminum plate is a first aluminum plate, the module further comprising one or more additional aluminum plates on which are mounted additional cells, each of the additional aluminum plates having edges that are bent upwards to form at least a partial box around the additional cells, the side panels extending along the first aluminum plate and the additional aluminum plates to connect them together, each of the aluminum plates supporting an associated primary optical element that directs sunlight to each of its associated cells

19. The module of claim 16 further comprising the primary optical element, the primary optical element being a Fresnel lens having a different lens portion corresponding to each of the cells.

20. The module of claim 1 wherein thermally coupling between the cells and the aluminum plate is formed by a path that contains at most only one non-metal layer.

21. The module of claim 1 wherein the patterned first metal interconnection layer is a copper layer.

22. The module of claim 1 wherein the patterned first metal interconnection layer is an electrically conductive paste layer.

23. The module of claim 1 wherein the patterned first metal interconnection layer is an electrically conductive ink layer.
